(19) United States
(12) Patent Application Publication
(10) Pub. No.: US 2025/0317114 A1
(43) Pub. Date: Oct. 9, 2025

(54) ISOLATION DEVICE

(71) Applicant: INDUSTRIAL TECHNOLOGY RESEARCH INSTITUTE, Hsinchu (TW)

(72) Inventors: Hsuan-Yu TSAI, Hsinchu City (TW); Tsan-Huang CHEN, Zhubei City (TW)

(73) Assignee: INDUSTRIAL TECHNOLOGY RESEARCH INSTITUTE, Hsinchu (TW)

(21) Appl. No.: 18/781,443

(22) Filed: Jul. 23, 2024

(30) Foreign Application Priority Data
Apr. 9, 2024 (TW) 113113102

(51) Int. Cl. H03F 3/45; G01R 33/07

(52) U.S. Cl. CPC H03F 3/45475; G01R 33/07

(57) ABSTRACT

An isolation circuit comprises: a plurality of coils generating magnetic fields in response to a received differential signal; a plurality of metal layers, with a first metal layer and a second metal layer forming a capacitor to sense a voltage change of the differential signal; a noise sensing circuit sensing a capacitor current generated by the second metal layer and converting into a first electrical signal; and a magnetic field sensing circuit sensing the magnetic fields generated by the coils and converting into a second electrical signal.

This application claims the benefit of Taiwan application Serial No. 113113102, filed Apr. 9, 2024, the disclosure of which is incorporated by reference herein in its entirety.

### TECHNICAL FIELD

The disclosure relates in general to an isolation device, particularly to an isolation device capable of enhancing common-mode transient suppression capability.

### BACKGROUND

Common Mode Transient Immunity (CMTI) refers to the resistance capability of circuit chips, electronic devices, or systems to common-mode interference. Common-mode interference refers to the impact of external abrupt voltage changes on signal transmission and reception, which may affect a plurality of chips or devices simultaneously.

CMTI is the ability of circuit devices to resist common-mode interference. Specifically, CMTI indicates the ability of chips or devices to quickly and effectively handle or ignore common-mode interference while in operation. A high CMTI indicates strong resistance to common-mode interference, enabling normal operation without being affected by external common-mode interference.

CMTI is a crucial indicator for applications requiring high stability and reliability, such as communication devices, precision instruments, and control systems. Devices with high CMTI can better cope with common-mode interference in various environments, ensuring the normal operation of the system.

To improve CMTI, there are various approaches currently employed. These approaches mainly focus on isolation structures, circuits, and signal encoding. Improving CMTI from a structural design perspective aims to enhance symmetry to eliminate the influence of common-mode noise through well-designed symmetric structures. For example, symmetric designs of components and packaging brackets are used in conjunction with the transmission and reception of differential signals.

Alternatively, CMTI can be improved from a circuit perspective to achieve common-mode interference suppression and compensation. Methods include signal filtering, interference filtering, or interference detection and compensation. Although improving CMTI solely from a circuit perspective can yield better results, it often requires occupying a larger circuit area, and the response speed of detection and compensation is typically positively correlated with power consumption.

Encoding can also be employed to improve CMTI, aiming to enhance signal anti-interference capabilities. Methods include pulse encoding, Frequency-shift keying, or On-off keying. Although improving CMTI through encoding results in better performance with more complex encoding, it simultaneously limits the width of pulse signals that can be transmitted.

Therefore, modern isolation devices often combine a plurality of approaches to address the shortcomings of individual isolation methods.

### SUMMARY

The disclosure relates to an isolation device that utilizes substantially equal-sized series-connected coils to receive the differential signals transmitted from the transmission terminal in order to obtain non-differential signals. Additionally, the disclosure employs a flat capacitor structure equal to or larger than the isolation barrier for noise sensing. Thus, the disclosure can enhance or utilize simple circuits to improve common-mode noise immunity and is suitable for transformer magnetic field-coupled isolation structures.

According to one embodiment, an isolation device is provided. The isolation device receives a differential signal from a transmission terminal. The isolation device comprises: a plurality of coils generating magnetic fields responsive to the received differential signal; a plurality of metal layers, wherein a first metal layer of the metal layers is located at a junction of the coils, and a second metal layer of the metal layers is positioned below the first metal layer, the first and the second metal layers forming a capacitor to sense a total voltage change of the differential signal; a noise sensing circuit, electrically coupled to the second metal layer, sensing a capacitor current generated by the second metal layer to convert into a first electrical signal; and a magnetic field sensing circuit, coupled to the coils, sensing the magnetic fields generated by the coils and converting into a second electrical signal.

According to another embodiment, an isolation device is provided. The isolation device receives a differential signal from a transmission terminal. The isolation device comprises: a plurality of coils generating a magnetic field in response to the received differential signal; a plurality of pads coupled to the coils; a metal layer located beneath a third pad of the pads, the metal layer and the third pad forming a capacitor to sense a total voltage change of the differential signal; a noise sensing circuit electrically coupled to the metal layer, sensing a capacitor current generated by the metal layer to convert into a first electrical signal; and a magnetic field sensing circuit coupled to the coils, sensing the magnetic field generated by the coils and converting into a second electrical signal.

### BRIEF DESCRIPTION OF THE DRAWINGS

FIG. 1 illustrates a functional block diagram and signal waveform diagram of the isolation device according to the first embodiment of the disclosure.

FIG. 2 shows a circuit diagram of an isolation device according to the first embodiment of the present disclosure.

FIGS. 3A and 3B show the circuit diagram and waveform diagram of an isolation device according to the second embodiment of the present disclosure.

FIG. 4 illustrates a functional block diagram of the isolation device according to the third embodiment of this disclosure.

FIG. 5 illustrates a functional block diagram of the isolation device according to the fourth embodiment of the disclosure.

FIGS. 6A to 6D show schematic diagrams of the distance between the upper and lower metal layers of capacitors in several embodiments of the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, one skilled person in the art would selectively implement part or all technical features of any embodiment of the disclosure or selectively combine part or all technical features of the embodiments of the disclosure.

The signal isolation device of the present embodiment creates a coupling path unrelated to the input signal through coil combinations, and can determine whether to follow or ignore the demodulated signal level by detecting changes in the path signal to enhance common-mode transient suppression capability.

Below, several embodiments of the isolation device of the disclosure will be described.

### First Embodiment

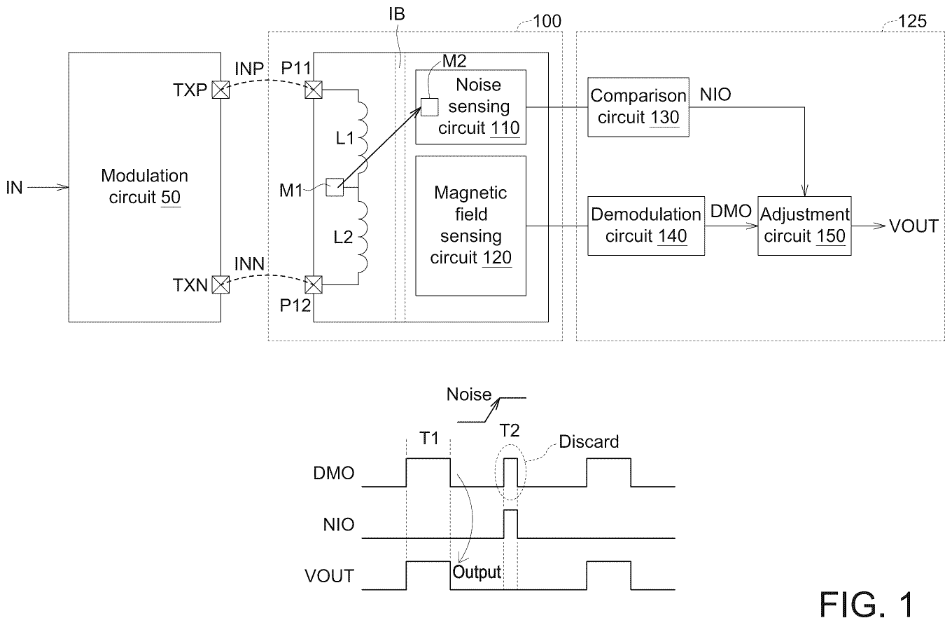

FIG. 1 illustrates a functional block diagram and signal waveform diagram of the isolation device according to the first embodiment of the disclosure. As shown in FIG. 1, the isolation device 100 according to the first embodiment of the disclosure includes: coils L1 and L2, a noise sensing circuit 110, a magnetic field sensing circuit 120, pads P11 and P12, metal layers M1 and M2, where the coils L1 and L2 and the metal layer M1 are isolated from the noise sensing circuit 110 and the magnetic field sensing circuit 120 by an isolation barrier IB. The metal layers M1 and M2 are located on both sides of the isolation barrier IB. The isolation device 100 is coupled to a first recovery circuit 125. The first recovery circuit 125 includes: a comparison circuit 130, a demodulation circuit 140, and an adjustment circuit 150. In FIG. 1, pads P11 and P12 are made of metal.

The isolation device 100 is coupled to the modulation circuit 50 of the transmission terminal. The modulation circuit 50 at the transmission terminal modulates the input signal IN into differential signals INP and INN. The isolation device 100 receives the differential signals INP and INN transmitted from the modulation circuit 50 at the transmission terminal.

The coils L1 and L2 are connected in series at the metal layer M1. The metal layer M1 is located at the junction of the coils L1 and L2. The coils L1 and L2 can sense the received differential signals INP and INN. In response to the received differential signals INP and INN, the coils L1 and L2 generate a magnetic field due to current changes. The coils L1 and L2 are substantially the same size.

The noise sensing circuit 110 is electrically coupled to the metal layer M2 (i.e., the metal layer M2 serves as a sensing node). The capacitor formed by the metal layers M1 and M2 can detect the variation of common mode voltage of the differential signals INP and INN. After detecting the change in common mode voltage, the capacitor generates a current to the noise sensing circuit 110 (via the metal layer M2). The noise sensing circuit 110 can detect the current of the capacitor and convert into an electrical signal, such as but not limited to, a voltage signal (also referred to as the first voltage signal or the first electrical signal). The first voltage signal or the first electrical signal generated by the noise sensing circuit 110 can also be regarded as representing whether the common mode noise is within a tolerable range. In an embodiment of the present disclosure, the noise sensing circuit 110 may include, but is not limited to, current-to-voltage conversion circuits such as resistors, transimpedance amplifiers, etc.

The magnetic field sensing circuit 120 is coupled to the coils L1 and L2. The magnetic field sensing circuit 120 can sense the magnetic field generated by the coils L1 and L2 and convert into an electrical signal, such as but not limited to, a voltage signal (also referred to as the second voltage signal or the second electrical signal). The second voltage signal or the second electrical signal is related to the differential signals INP and INN. In an embodiment of the present disclosure, the magnetic field sensing circuit 120 may include, but is not limited to, a combination of magnetic field sensing elements and regulation circuits (not shown). The magnetic field sensing elements may include, but are not limited to, coils, Hall elements, etc.

The comparison circuit 130 is electrically coupled to the noise sensing circuit 110. The comparison circuit 130 receives the first voltage signal (or the first electrical signal) transmitted from the noise sensing circuit 110. The comparison circuit 130 compares the first voltage signal (or the first electrical signal) transmitted from the noise sensing circuit 110 with a tolerance threshold to obtain a comparison result NIO. When the first voltage signal (or the first electrical signal) transmitted from the noise sensing circuit 110 is lower than the tolerance threshold, the comparison result NIO of the comparison circuit 130 is the first comparison result (such as but not limited to, a logic low signal). When the first voltage signal (or the first electrical signal) transmitted from the noise sensing circuit 110 is higher than the tolerance threshold, the comparison result NIO of the comparison circuit 130 is the second comparison result (such as but not limited to, a logic high signal).

The demodulation circuit 140 is electrically coupled to the magnetic field sensing circuit 120. The demodulation circuit 140 demodulates the second voltage signal (or the second electrical signal) transmitted from the magnetic field sensing circuit 120 into a demodulated signal DMO.

The adjustment circuit 150 is electrically coupled to the comparison circuit 130 and the demodulation circuit 140. The adjustment circuit 150 generates an output signal VOUT based on the comparison result NIO of the comparison circuit 130 and the demodulated signal DMO generated by the demodulation circuit 140. The adjustment circuit 150 determines whether to output the demodulated signal DMO generated by the adjustment demodulation circuit 140 as the output signal VOUT (i.e., the output signal VOUT follows the demodulated signal DMO), or to discard the demodulated signal DMO generated by the demodulation circuit 140 to keep the output signal VOUT at the current potential (i.e., the output signal VOUT remains unchanged) based on the comparison result NIO of the comparison circuit 130. For example, when the comparison result NIO of the comparison circuit 130 is the first comparison result (such as but not limited to, a logic low signal), indicating that the first voltage signal (or the first electrical signal) transmitted from the noise sensing circuit 110 is lower than the tolerance threshold (i.e., the common mode noise is still within an acceptable range), the adjustment circuit 150 outputs the demodulated signal DMO generated by the adjustment demodulation circuit 140 as the output signal VOUT, so that VOUT=DMO. On the other hand, when the comparison result NIO of the comparison circuit 130 is the second comparison result (such as but not limited to, a logic high signal), indicating that the first voltage signal (or the first electrical signal) transmitted from the noise sensing circuit 110 is higher than the tolerance threshold (i.e., the common mode noise is higher than the acceptable range), the adjustment circuit 150 discards the demodulated signal DMO generated by the demodulation circuit 140 as the output, so that VOUT continues to remain at the current potential.

Please refer again to the signal waveform diagram of FIG. 1. At time T1, since the comparison result NIO of the comparison circuit 130 is the first comparison result (such as but not limited to, a logic low signal), indicating that the first voltage signal (or the first electrical signal) transmitted from the noise sensing circuit 110 is lower than the tolerance threshold (i.e., the common mode noise is still within an acceptable range), the adjustment circuit 150 outputs the demodulated signal DMO generated by the adjustment demodulation circuit 140 as the output signal VOUT (VOUT=DMO).

On the other hand, at time T2, due to the influence of common mode noise, the comparison result NIO of the comparison circuit 130 is the second comparison result (such as but not limited to, a logic high signal). Therefore, at time T2, when the first voltage signal (or the first electrical signal) transmitted from the noise sensing circuit 110 is higher than the tolerance threshold (i.e., the common mode noise exceeds the acceptable range), the adjustment circuit 150 discards the demodulated signal DMO generated by the demodulation circuit 140 as the output, so that VOUT continues to remain at the current potential.

From the above description and waveform diagram of FIG. 1, it can be seen that in the isolation device 100 of the first embodiment of the present disclosure, when the common mode noise is too high, the isolation device 100 has common mode transient suppression capability (i.e., the output signal VOUT is not affected by the common mode noise).

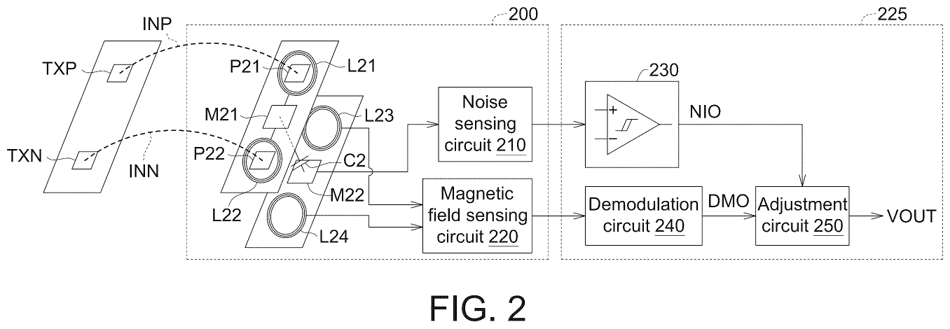

FIG. 2 shows a circuit diagram of an isolation device 200 according to the first embodiment of the present disclosure. As shown in FIG. 2, the isolation device 200 can be used to implement the isolation device 100 of FIG. 1.

The isolation device 200 includes: coils L21-L24, a noise sensing circuit 210, a magnetic field sensing circuit 220, metal layers M21 and M22, pads P21 and P22. The second recovery circuit 225 includes: a comparison circuit 230, a demodulation circuit 240, and an adjustment circuit 250. The pads P21 and P22 are located within the coils L21 and L22. The isolation device 200 is coupled to the second recovery circuit 225. The Coils L21 and L22 are electrically coupled to the metal layer M21. The metal layers M21 and M22 correspond to the metal layers M1 and M2 of FIG. 1.

The coils L21 and L22 are connected in series. Essentially, the coils L21 and L22 are the same as the coils L1 and L2 in FIG. 1. The metal layer M21 is located at the junction of the coils L21 and L22. The position of the metal layer M22 can be at the same height or lower than the coils L23 and L24 (explained below). The metal layers M21 and M22 form a capacitor C2. The metal layer M22 is positioned below the metal layer M21. The capacitor C2 formed by the metal layers M21 and M22 can detect the change of common mode voltage of the differential signals INP and INN (i.e., the capacitor C2 can detect the total voltage change of differential signals INP and INN). After detecting the change in common mode voltage, the capacitor C2 generates a current to the noise sensing circuit 210. The metal layers M21 and M22 correspond to the metal layers M1 and M2 in FIG. 1.

The coils L21-L24 can detect the received differential signals INP and INN. In response to the received differential signals INP and INN, the coils L21 and L22 generate a magnetic field due to current change. The coils L23 and L24 can detect the magnetic field generated by the coils L21 and L22, thereby generating corresponding electrical signals for the differential signals INP and INN.

In detail, the coils L21 and L23 sense the differential signal INP, while the coils L22 and L24 sense the differential signal INN.

In FIG. 2, the noise sensing circuit 210 is coupled to the metal layer M22 (i.e., metal layer M22 serves as a sensing node). The noise sensing circuit 210 can be implemented by a transimpedance amplifier (TIA) (i.e., the noise sensing circuit 210 includes a transimpedance amplifier), but the present disclosure is not limited to this. The noise sensing circuit 210 converts the current of the capacitor C2 into voltage. The noise sensing circuit 210 is essentially the same as or similar to the noise sensing circuit 110 in FIG. 1.

The magnetic field sensing circuit 220 is coupled to the coils L23 and L24. The magnetic field sensing circuit 220 can be implemented by a combination of magnetic field sensing elements and regulation circuits (not shown), but the present disclosure is not limited to this. Magnetic field sensing elements can be coils or Hall sensors. A Hall sensor is a transducer that converts changes in magnetic field into changes in output voltage. The magnetic field sensing circuit 220 is essentially the same as or similar to the magnetic field sensing circuit 120 in FIG. 1. The coils L21 and L23 sense the differential signal INP, while the coils L22 and L24 sense the differential signal INN. The magnetic induction results of the coils L21-L24 are input to the magnetic field sensing circuit 220.

The comparison circuit 230, the demodulation circuit 240, and the adjustment circuit 250 are essentially the same as or similar to the comparison circuit 130, the demodulation circuit 140, and the adjustment circuit 150 in FIG. 1.

Similarly, in the isolation device 200 of the first embodiment of the present disclosure, when the common mode noise is too high, the isolation device 200 has common mode transient suppression capability (i.e., the output signal VOUT is not affected by the common mode noise).

### Second Embodiment

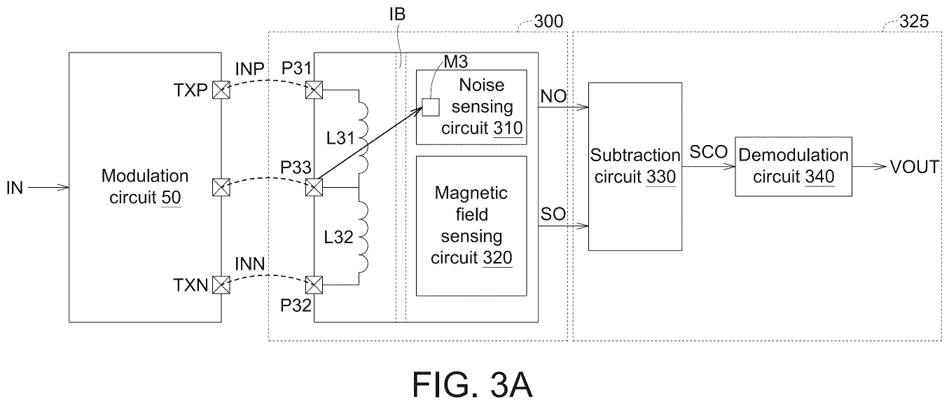

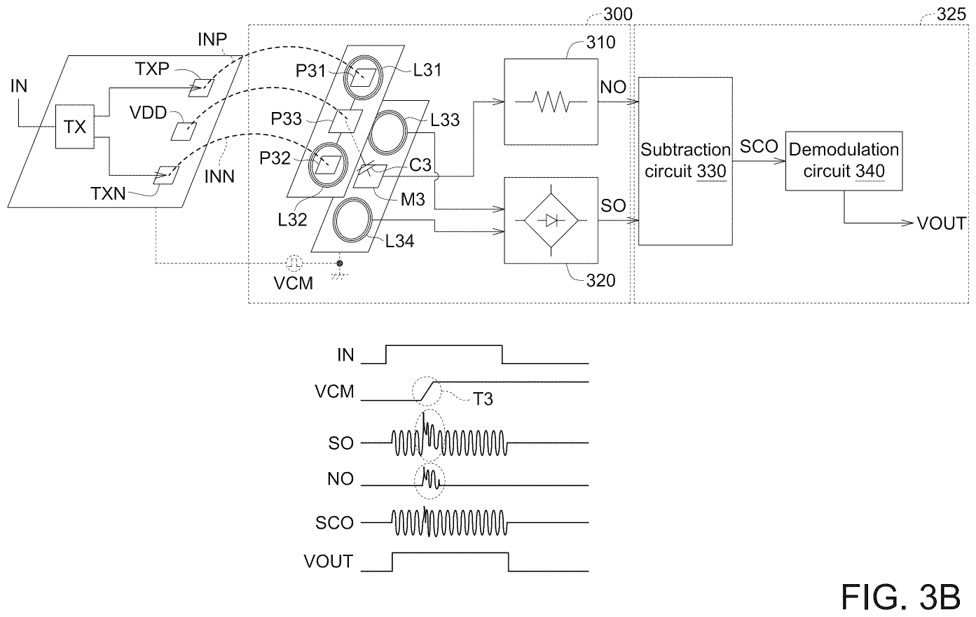

FIGS. 3A and 3B show the circuit diagram and waveform diagram of an isolation device 300 according to the second embodiment of the present disclosure. FIG. 3B illustrates an embodiment of the isolation device depicted in FIG. 3A. The isolation device 300 includes coils L31-L34, a noise sensing circuit 310, a magnetic field sensing circuit 320, metal layer M3, and pads P31-P33. The isolation device 300 is coupled to the third recovery circuit 325. The third recovery circuit 325 includes a subtraction circuit 330 and a demodulation circuit 340. The pads P31 and P32 are located within the coils L31 and L32. In FIG. 3A, the coils L31 and L32 are electrically coupled to the pad P33.

The coils L31 and L32 are connected in parallel. The position of the metal layer M3 can be at the same height or lower than the coils L33 and L34 (explained below). The pad P33 and the metal layer M3 form a capacitor C3. The metal layer M3 is positioned below the pad P33. The capacitor C3 formed by the pad P33 and the metal layer M3 can detect the change of common mode voltage of the differential signals INP and INN. After detecting the change in common mode voltage, the capacitor C3 generates a current to the noise sensing circuit 310.

The coils L31-L34 detect the received differential signals INP and INN. In response to the received differential signals INP and INN, the coils L31 and L32 generate a magnetic field due to the change in current. The coils L33 and L34 detect the magnetic field generated by the coils L31 and L32, thereby producing corresponding electrical signals for the differential signals INP and INN.

In detail, the coils L31 and L33 sense the differential signal INP, while the coils L32 and L34 sense the differential signal INN.

In FIGS. 3A and 3B, the noise sensing circuit 310 is coupled to the metal layer M3 (i.e., the metal layer M3 serves as the sensing node). The noise sensing circuit 310 can be implemented by current-to-voltage conversion circuits such as resistors or transimpedance amplifiers, but the present disclosure is not limited thereto. The noise sensing circuit 310 converts the current of the capacitor C3 (transmitted through the metal layer M3) into voltage. That is, the noise sensing circuit 310 receives the capacitor current generated by the metal layer M3 and converts into an electrical signal NO.

The magnetic field sensing circuit 320 is coupled to the coils L33 and L34. The magnetic field sensing component of the magnetic field sensing circuit 320 can be realized by a combination of a Hall sensor and regulation circuit (not shown), but the present disclosure is not limited thereto. The magnetic field sensing component can detect the magnetic field of the signals transmitted by the coils L31 and L32. In other words, the magnetic field sensing circuit 320 detects the magnetic field of the signals by the coils L33 and L34 to obtain another electrical signal SO.

The subtraction circuit 330 is coupled to the noise sensing circuit 310 and the magnetic field sensing circuit 320. The subtraction circuit 330 generates a subtraction result SCO based on the output NO (which can be a voltage signal) of the noise sensing circuit 310 and the output SO (which can be a voltage signal) of the magnetic field sensing circuit 320. For example, the subtraction circuit 330 subtracts the output SO of the magnetic field sensing circuit 320 (which can be a voltage signal) from the output NO of the noise sensing circuit 310 (which can be a voltage signal) to generate the subtraction result SCO.

The demodulation circuit 340 is coupled to the subtraction circuit 330. The demodulation circuit 340 is used to demodulate the subtraction result SCO from the subtraction circuit 330 to generate the output voltage VOUT.

Please refer to the waveform diagram of isolation device 300. For clarity, the common-mode voltage VCM of the differential signals INP and INN are shown in the waveform diagram. When interference appears in the common-mode voltage VCM of the differential signals INP and INN, as shown at time T3, interference will also appear in the outputs NO of the noise sensing circuit 310 and SO of the magnetic field sensing circuit 320, and the interference phases of both (outputs NO of the noise sensing circuit 310 and SO of the magnetic field sensing circuit 320) are basically the same. Therefore, in the second embodiment of this disclosure, the interference of this common-mode voltage can be subtracted via the subtraction circuit 330 to prevent the interference of the common-mode voltage from appearing in the subtraction result SCO of the subtraction circuit 330 and the output voltage VOUT of the demodulation circuit 340.

Similarly, in the second embodiment of this disclosure, when the common-mode noise is too high, the isolation device 300 has the common-mode transient suppression capability (i.e., the output signal VOUT is not affected by common-mode noise).

### Third Embodiment

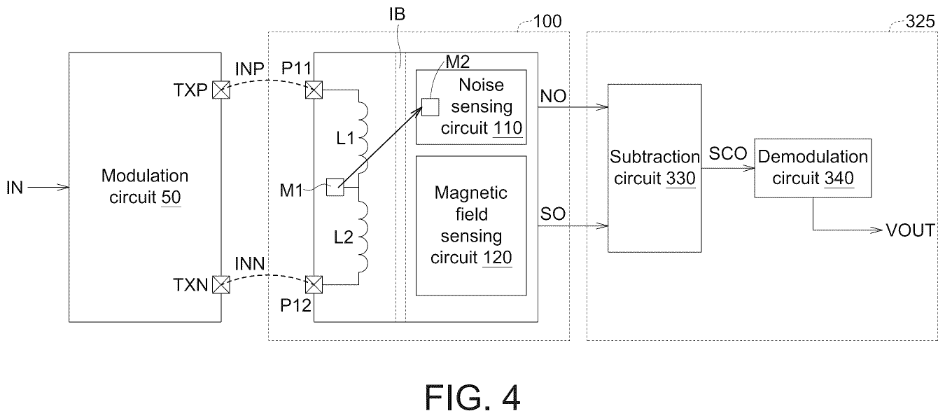

FIG. 4 illustrates a functional block diagram of the isolation device according to the third embodiment of this disclosure. As the isolation device 100 of FIG. 4 is essentially the same as the isolation device in FIG. 1, its details are omitted here.

The isolation device 100 of FIG. 4 is coupled to the third recovery circuit 325.

The operational details of the third embodiment can basically be inferred from the descriptions of the first and second embodiments above, so the details are omitted here.

### Fourth Embodiment

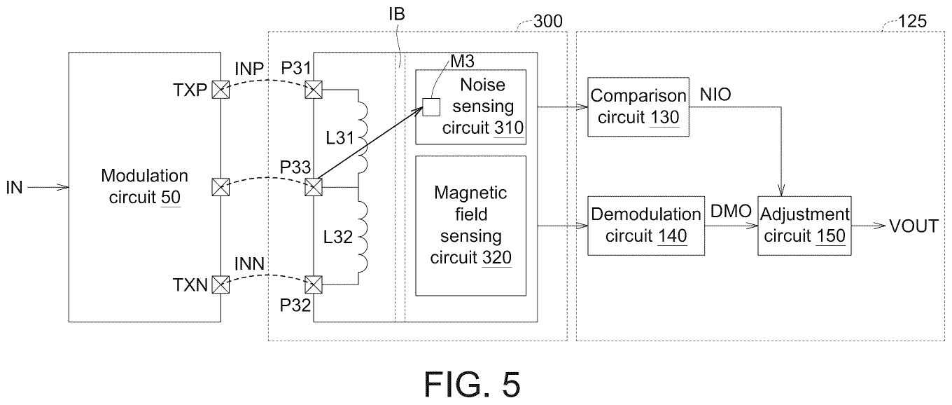

FIG. 5 illustrates a functional block diagram of the isolation device according to the fourth embodiment of the disclosure. The isolation device 300 of FIG. 5 is essentially the same as the isolation devices of FIGS. 3A and 3B, so the details are omitted here.

The isolation device 300 of FIG. 5 is coupled to the first recovery circuit 125.

The operational details of the fourth embodiment can basically be inferred from the descriptions of the first and second embodiments above, so the details are omitted here.

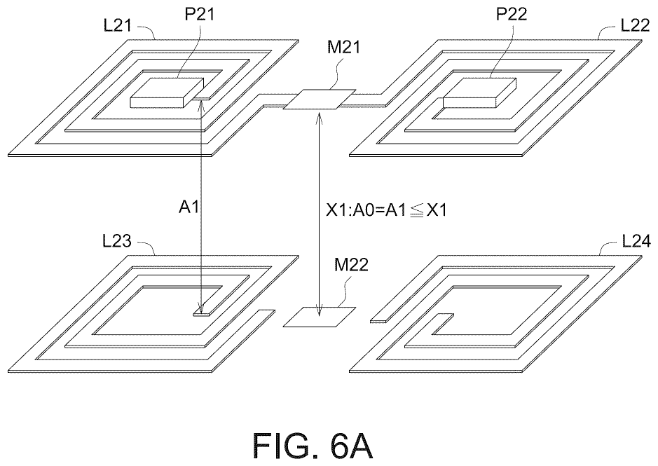

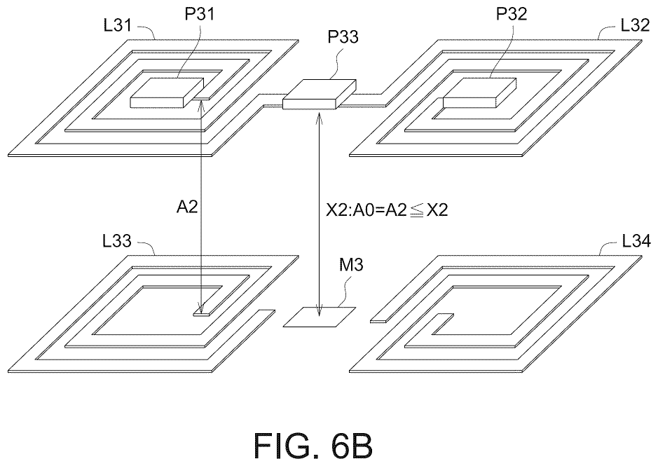

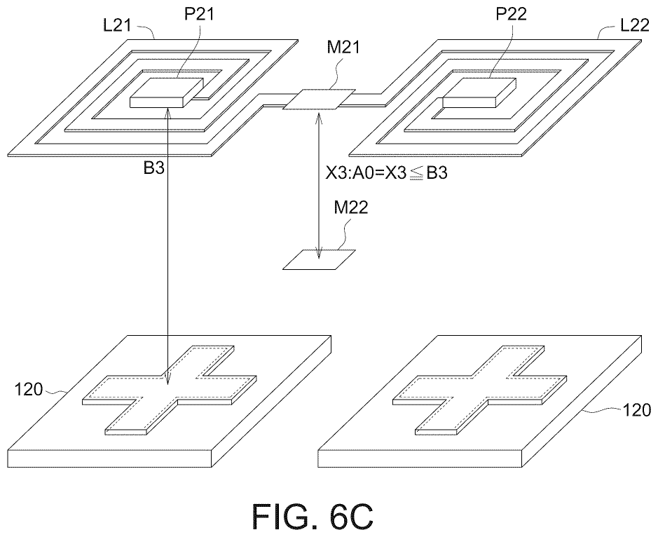

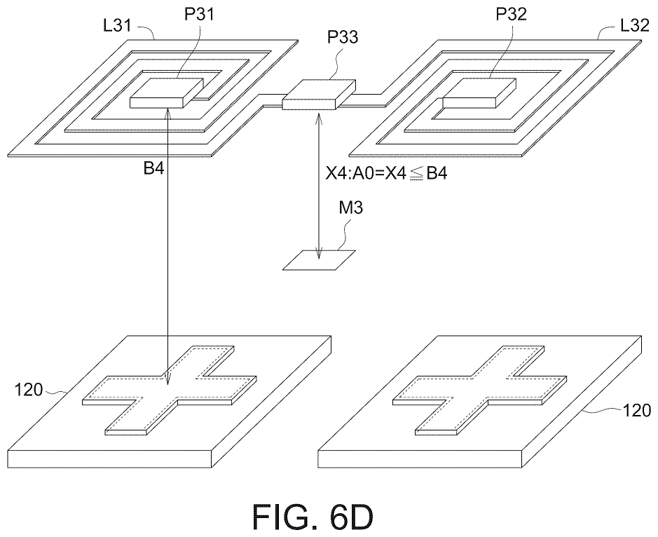

FIGS. 6A to 6D show schematic diagrams of the distance between the upper and lower metal layers of capacitors in several embodiments of the disclosure.

In FIG. 6A, the maximum withstand voltage of the isolation device is related to the material and thickness A0 of the isolation barrier. The distance between the coil L21 and coil L23 is A1, while the distance between the metal layers M21 and M22 is X1, where A0=A1≤X1.

In FIG. 6B, the distance between the coil L31 and the coil L33 is A2, while the distance between the pad P33 and the metal layer M3 is X2, where A0=A2≤X2.

In FIG. 6C, the distance between the metal layers M21 and M22 is X3, the distance between the coil L21 and the magnetic field sensing circuit 120 (such as the Hall element of magnetic field sensing circuit 120) is B3, where A0=X3≤B3.

In FIG. 6D, the distance between the pad P33 and the metal layer M3 is X4, and the distance between the coil L31 and the magnetic field sensing circuit 120 (such as the Hall element of magnetic field sensing circuit 120) is B4, where A0=X4≤B4.

As described in the above embodiments, the embodiments of the disclosure utilize features such as coils of equal size and differential signals to improve common-mode noise immunity, which can be achieved through simple circuits. Therefore, compared to the prior art, the embodiments of the disclosure can increase common-mode noise immunity with lower circuit complexity. The isolation devices of the embodiments of the disclosure are compatible with existing processes, allowing the use of magnetic coupling structure for signal transmission with coils and sensing of common mode noise to achieve interference-resistant designs.

Although the present disclosure may describe many specific details, these should not be construed as limiting the scope of the claimed disclosure but rather as descriptions of specific embodiments. In the description herein, certain features described in the context of a single embodiment may also be implemented in combination in a single embodiment. Conversely, various features described in the context of a single embodiment may also be implemented separately or in any suitable subcombination in a plurality of embodiments. Furthermore, while features may initially be described as operating in a particular combination or even initially described as such a combination, in some cases, one or more features may be omitted from the combination, and the described combination may be directed to a subcombination or variation of a subcombination. Likewise, while operations may be depicted as being performed in a specific order in the drawings, this should not be understood as requiring that the operations must be performed in the specific order or sequence shown or that all the depicted operations must be performed to achieve the desired result.

Although the above embodiments of the present disclosure only reveal some examples and implementations, changes, modifications, and enhancements may be made to the disclosed examples, implementations, and other implementations based on the disclosed content.

While this document may describe many specifics, these should not be construed as limitations on the scope of an disclosure that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in a plurality of embodiments separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. An isolation device, receiving a differential signal from a transmission terminal, the isolation device comprising:
a plurality of coils generating magnetic fields responsive to the received differential signal;
a plurality of metal layers, wherein a first metal layer of the metal layers is located at a junction of the coils, and a second metal layer of the metal layers is positioned below the first metal layer, the first and the second metal layers forming a capacitor to sense a total voltage change of the differential signal;
a noise sensing circuit, electrically coupled to the second metal layer, sensing a capacitor current generated by the second metal layer to convert into a first electrical signal; and
a magnetic field sensing circuit, coupled to the coils, sensing the magnetic fields generated by the coils and converting into a second electrical signal.

2. The isolation device of claim 1, wherein:
the coils are substantially of the same size; and
the number of the coils is an even number.

3. The isolation device of claim 1, wherein the isolation device is coupled to a first recovery circuit comprising:
a comparator circuit, electrically coupled to the noise sensing circuit, generating a comparison result based on the first electrical signal;
a demodulation circuit, electrically coupled to the magnetic field sensing circuit, demodulating the second electrical signal into a demodulated signal; and
an adjustment circuit, electrically coupled to the comparator circuit and the demodulation circuit, determining whether an output signal of the adjustment circuit follows the demodulated signal or discards the demodulated signal based on the comparison result.

4. The isolation device of claim 3, wherein when the first electrical signal of the comparator circuit is below a tolerance threshold, the adjustment circuit decides that the output signal of the adjustment circuit follows the demodulated signal to output the demodulated signal as the output signal.

5. The isolation device of claim 3, wherein when the first electrical signal exceeds a tolerance threshold, the adjustment circuit discards the demodulated signal to maintain the output signal of the adjustment circuit.

6. The isolation device of claim 3, wherein:
the noise sensing circuit is a current-voltage conversion circuit, comprising a resistor or a transimpedance amplifier; and
the magnetic field sensing circuit comprises a magnetic field sensing element, comprising a coil or a Hall element.

7. The isolation device of claim 1, wherein the isolation device is coupled to a third recovery circuit comprising:
a subtraction circuit, coupled to the noise sensing circuit and the magnetic field sensing circuit, generating a subtraction result based on the first electrical signal of the noise sensing circuit and the second electrical signal of the magnetic field sensing circuit; and
a demodulation circuit, coupled to the subtraction circuit, demodulating the subtraction result of the subtraction circuit to generate an output voltage.

8. The isolation device of claim 1, wherein:
a thickness of an isolation barrier material of the isolation device is denoted as A0,
a distance between a first coil and a third coil among the coils is denoted as A1,
a distance between the first metal layer and the second metal layer is denoted as X1, wherein A0=A1≤X1.

9. The isolation device of claim 1, wherein:
a thickness of an isolation barrier material of the isolation device is denoted as A0,
a distance between the first metal layer and the second metal layer is denoted as X3,
a distance between a first coil among the coils and the magnetic field sensing circuit is denoted as B3, wherein A0=X3≤B3.

10. An isolation device, receiving a differential signal transmitted by a transmission terminal, comprising:
a plurality of coils generating a magnetic field in response to the received differential signal;
a plurality of pads coupled to the coils;
a metal layer located beneath a third pad of the pads, the metal layer and the third pad forming a capacitor to sense a total voltage change of the differential signal;
a noise sensing circuit electrically coupled to the metal layer, sensing a capacitor current generated by the metal layer to convert into a first electrical signal; and
a magnetic field sensing circuit coupled to the coils, sensing the magnetic field generated by the coils and converting into a second electrical signal.

11. The isolation device according to claim 10, wherein,
the coils are substantially of the same size; and
the number of the coils is an even number.

12. The isolation device according to claim 10, wherein the isolation device is coupled to a third recovery circuit, the third recovery circuit comprising:
a subtraction circuit coupled to the noise sensing circuit and the magnetic field sensing circuit, the subtraction circuit generating a subtraction result based on the first electrical signal from the noise sensing circuit and the second electrical signal from the magnetic field sensing circuit; and
a demodulation circuit coupled to the subtraction circuit, the demodulation circuit demodulating the subtraction result of the subtraction circuit to generate an output voltage.

13. The isolation device according to claim 10, wherein the noise sensing circuit is a current-to-voltage conversion circuit, the current-to-voltage conversion circuit comprising a resistor or a transimpedance amplifier; and the magnetic field sensing circuit comprises a magnetic field sensing element, comprising a coil or a Hall element.

14. The isolation device according to claim 10, wherein the isolation device is coupled to a first recovery circuit, the first recovery circuit comprising:
a comparison circuit electrically coupled to the noise sensing circuit, the comparison circuit generating a comparison result based on the first electrical signal;
a demodulation circuit electrically coupled to the magnetic field sensing circuit, the demodulation circuit demodulating the second electrical signal into a demodulated signal; and
an adjustment circuit electrically coupled to the comparison circuit and the demodulation circuit, the adjustment circuit determining whether an output signal of the adjustment circuit follows the demodulated signal or discards the demodulated signal based on the comparison result.

15. The isolation device according to claim 14, wherein when the first electrical signal of the comparison circuit is lower than a tolerance threshold, the adjustment circuit determines that the output signal of the adjustment circuit follows the demodulated signal to output the demodulated signal.

16. The isolation device according to claim 14, wherein when the first electrical signal exceeds a tolerance threshold, the adjustment circuit discards the demodulated signal to maintain the output signal of the adjustment circuit.

17. The isolation device according to claim 10, wherein,
a thickness of an isolation barrier material of the isolation device is A0,
a distance between a first coil and a third coil of the coils is A2,
a distance between the third pad and the metal layer is X2,
wherein, A0=A2≤X2.

18. The isolation device according to claim 10, wherein,
a thickness of an isolation barrier material of the isolation device is A0,
a distance between the third pad and the metal layer is X4,
a distance between a first coil of the coils and the magnetic field sensing circuit is B4,
wherein, A0=X4≤B4.
